(19) United States
(12) Patent Application Publication
(10) Pub. No.: US 2022/0108172 A1
(43) Pub. Date: Apr. 7, 2022

(54) GENERATING A SIMPLIFIED MODEL FOR XIL SYSTEMS

(71) Applicant: Ford Global Technologies, LLC, Dearborn, MI (US)

(72) Inventor: Turgay Isik Aslandere, Aachen (DE)

(73) Assignee: Ford Global Technologies, LLC, Dearborn, MI (US)

(21) Appl. No.: 17/490,392

(22) Filed: Sep. 30, 2021

(30) Foreign Application Priority Data
Oct. 2, 2020 (DE) 102020212505.8

(51) Int. Cl. G06N 3/08; G06N 3/04

(52) U.S. Cl. CPC G06N 3/08; G06N 3/0445

(57) ABSTRACT

Generating a simplified model for an XiL system includes determining a stipulated parameter characterizing model complexity, for a starting model; generating starting model input and output data; training a neural network to generate a simplified model having a lower complexity than the starting model and where a stipulated lower threshold value for a parameter characterizing model reliability is exceeded; generating a simplified model using the trained neural network; determining a parameter characterizing the complexity for the simplified model; if the determined complexity of the generated simplified model is lower than that of the starting model, testing the generated simplified model using a test set of the generated starting model input and output data, which differs from the training set, and determining a parameter of the generated simplified model characterizing reliability; if the determined reliability of the simplified model exceeds the stipulated threshold value, outputting the simplified model.

### CROSS-REFERENCE TO RELATED APPLICATIONS

This patent application claims priority to German Patent Application No. 102020212505.8, filed Oct. 2, 2021, which is hereby incorporated by reference in its entirety.

### BACKGROUND

Self-driving motor vehicles (sometimes also called autonomous vehicles) are motor vehicles which can drive, steer and park without the influence of a human driver (highly automated driving or autonomous driving). The driver's seat can remain unoccupied; there are possibly no steering wheel, no brake pedal and no gas pedal. Self-driving motor vehicles can capture their environment with the aid of different sensors and can determine their position and the position of other road users from the information obtained, can head for a destination in cooperation with the navigation software.

The emergence of intelligent mobility solutions and automated driving functions entails new challenges when testing such systems. Physical prototyping and/or intensive real test drives is/are extremely challenging. For this reason, new technologies for virtual engineering have been developed in recent years. An important prerequisite for testing such systems is the provision of X-in-the-Loop frameworks (XiL systems) which make it possible to test the developed software on different platforms, for example MiL, SiL, HiL, DiL, with a real ECU in real prototypes.

The XiL tests may be, for example, MiL (Model-in-the-Loop), SiL (Software-in-the-Loop), HiL (Hardware-in the-Loop) and/or DiL (Driver-in-the-Loop). In this case, MiL comprises the construction of models for a controlled system and an ECU as well as closed-loop control logic with a closed-loop control strategy for behavioral simulation, SiL comprises the creation of models in the target language of the ECU for automated testing in software developments, HiL denotes a method in which an embedded system (for example a real electronic ECU or a real mechatronic component, the hardware) is connected to an adapted counterpart via its inputs and outputs, and DiL is understood as meaning a combination of the HiL simulation with a driving simulator in a DiL simulation environment.

In this case, an ECU or control unit is understood as meaning an electronic module designed for the open-loop or closed-loop control of other components, such as components of a motor vehicle, using an open-loop or open-loop or closed-loop control strategy, for example. At least one ECU, which has the software to be tested, and a model, which simulates the behavior of the system, are typically used in the tests.

The document DE 10 2018 206 188 A1 describes a system for carrying out XiL tests of components of self-driving motor vehicles, wherein tests can be carried out on a plurality of XiL platforms. The document US 2019/0303759 A1 describes the use of neural networks to test a virtual vehicle in a simulated environment, wherein the physical sensor data used to train the neural network are generated by a vehicle in a real environment.

XiL elements are usually used to test software which is intended to be used to autonomously implement specific functions. In this case, hardware models (hardware in loop, processor in loop) are used, for example as software models (software in loop), to configure the test and checking process in order to reduce costs of prototypes and the performance of real tests, in particular. On account of the increasing number of hardware and software elements in motor vehicle systems, for example in driver assistance systems, and the increasing number of drive train elements, the number of required tests before a prototype can be issued is increasing. As a result, the number of XiL models which are needed for different configurations and tests is likewise increasing.

Apart from this, these models are becoming increasingly more complex and computationally more complicated. In addition, the models should be able to operate in real time or to provide a performance in real time. This is important, in particular, in connection with test and verification processes. However, the modern very complex models require a large amount of computing capacity in order to be able to be executed in real time. As the models, for example ADAS models, drive train models etc., become more complex, the existing XiL computing units which comprise real-time processors (for example dSpace Scalexio Boxes) reach their limits. Under certain circumstances, they are not able to comply with the necessary requirements. Therefore, a corresponding complex model cannot be used in such a case.

### SUMMARY

The present disclosure includes generating a simplified model for use in an XiL system. Disclosed herein are methods and apparatuses for generating or producing simpler models, wherein the the tests which are required under certain circumstances are more efficient. Also disclosed is a data processing apparatus, a computer program, an arrangement for carrying out XiL tests of components of motor vehicles, in particular self-driving motor vehicles, a method for carrying out XiL tests, and a computer-readable storage medium.

The method for generating a simplified model for use in an XiL system, in particular on at least one XiL test platform or in an XiL test method, comprises the following steps: at least one stipulated parameter, which quantitatively characterizes the complexity of a starting model, is determined for at least one starting model. In a further step, input data and output data of the at least one starting model are generated. In a next step, a neural network is trained using a training set of the generated input data and output data of the at least one starting model in order to generate, in particular develop, a simplified model which has a lower degree of complexity than the at least one starting model and in which a stipulated lower threshold value for at least one parameter quantitatively characterizing the reliability of a model is undershot.

A simplified model is generated using the trained neural network. The parameter, which characterizes the complexity, is determined for the simplified model. If the determined complexity of the generated simplified model is lower than that of the starting model, the generated simplified model is tested using a test set of the generated input and output data of the at least one starting model, which test set differs from the training set. In this case, the at least one parameter of the generated simplified model which characterizes the reliability is determined. If the determined reliability of the simplified model undershoots the stipulated threshold value, the simplified model is output.

It is also possible to convert complex and non-real-time capable models into resilient simplified models which are suitable for operation in real time, without reducing the reliability of the model in an undesirable manner in the process.

The parameter which quantitatively characterizes the complexity of the starting model may comprise, for example, the number of computing operations for each input data item and/or the required computing time for executing an algorithm representing the model and/or the required storage space requirement for executing an algorithm representing the model. The parameter which quantitatively characterizes the reliability of the starting model may comprise a measure of the deviation of the output data generated by the model from the expected output data, that is to say the output data to be provided by a real application component or application function.

An appropriate selection and stipulation of parameters which quantitatively characterize the complexity of a model and which characterize the reliability of the latter make it possible to comprehensibly determine whether and the extent to which the model generated by the neural network is simpler than the starting model and whether and how this has an effect on its reliability.

The neural network may be in the form of a deep neural network. Deep neural networks are mainly used to generalize training data and to make predictions, wherein trained weighting is used. Deep neural networks are able to learn the behavior of complex systems. In this case, the reliability increases with the amount of available data. Since XiL models are able to generate an unlimited number of training data items, it is possible for deep neural networks to learn the behavior of these models and to be able to make predictions with a high degree of precision. Deep neural networks are therefore suitable for transforming individual complex models into more general and computationally less complicated models.

In a further variant, the at least one starting model is in the form of a sequence of a number of models. In other words, the starting model may have a number of starting models which can be used in succession. The neural network may be in the form of a recurrent neural network. This is advantageous, in particular, if the starting model is in the form of a sequence of a number of models. In this case, two or more complex starting models can be converted into a single simplified model. As a result, the complexity of the respective XiL system is considerably simplified and its performance is considerably improved. In particular, this enables real-time use.

In a similar manner to the deep neural networks, recurrent neural networks (RNN) are used to generalize training data constructed from series of information. Recurrent neural networks can be easily trained using data comprising sequences of input data and output data of models which are computationally complicated. Each RNN cell may have an additional embedded layer where the training data include categorical variables. Furthermore, the RNN cells may receive input data from a convolutional network layer. The activity diagram of a recurrent neural network for generating simplified models is constructed in a similar manner to that of a neural network.

It is advantageous if the models are slightly overfitted in the training phase of the neural network, wherein the training reliability is higher than the test reliability. The background of this is that slightly overfitted AI models (AI—artificial intelligence) can make more accurate predictions with the repeated input data if sufficient data are available. In the case of a highly overfitted model, regulating techniques, such as the Drop Out or L2 and L1, can be used for regulation.

The method can be designed to generate a model for simulating at least one function of a motor vehicle, preferably a self-driving motor vehicle. This may be, for example, a driver assistance function and/or a function of the drive train of the motor vehicle.

The data processing apparatus according to the disclosure comprises means for carrying out a method according to the disclosure described above. The apparatus may have, in particular, a device for stipulating at least one parameter characterizing the complexity of the starting model and a device for determining this parameter. The apparatus may also comprise a device for stipulating and/or determining a parameter which quantitatively characterizes the reliability of a model. Furthermore, the apparatus may have one or more devices for generating input and output data of at least one starting model. The apparatus preferably comprises a neural network and a device for training the latter. In addition, the apparatus may have a device for outputting a model generated using the neural network.

The data processing apparatus may be in the form of a hardware element which comprises a computing unit for executing neural network algorithms and is designed to connect a number of XiL units or XiL elements. The computing unit may be, for example, Raspberry Pi, dSpace Microbox or a computer. The apparatus may have, for example, communication interfaces for connection to a number of XiL units, for example USB interfaces, Ethernet interfaces, in particular TCP/IP, UDP connectors, or CAN interfaces.

The computer program according to the disclosure comprises instructions which, when the program is executed by a computer, cause the latter to carry out the method according to the disclosure described above.

The arrangement according to the disclosure, which may be a system for example, for carrying out XiL tests of components of motor vehicles, for example self-driving motor vehicles, comprises a plurality of XiL models connected to one another for the purpose of transmitting data. The arrangement is designed to replace at least one of the XiL models with a simplified model generated using a method according to the disclosure described above. This has the advantage that XiL tests can be carried out using the arrangement according to the disclosure in a computationally simpler manner and possibly in real time.

In one advantageous variant, the arrangement is designed to replace a plurality of the XiL models with a single, that is to say common, simplified model generated using a method as described above. In a further variant, the arrangement may comprise a data processing apparatus according to the disclosure described above and/or a computer program according to the disclosure described above.

The method for carrying out XiL tests, in particular of components of motor vehicles, for example self-driving motor vehicles, comprises the following steps: in a first step, an XiL system which comprises at least one starting model is initialized. In a next step, a simplified model of the at least one starting model is generated using a method according to the disclosure described above. At least one or the at least one starting model is then replaced with the simplified model in the XiL system. The XiL test is then carried out using the XiL system comprising the simplified model. The method according to the disclosure for carrying out XiL tests has the advantages which have already been mentioned above. It can be carried out in real time, in particular, and makes it possible to flexibly and efficiently convert complex partial models of the XiL system into simplified and more powerful models.

The computer program according to the disclosure for carrying out XiL tests comprises instructions which, when the program is executed by a computer, cause the latter to carry out an above-described method according to the disclosure for carrying out XiL tests. It has the advantages which have already been mentioned.

The computer-readable storage medium according to the disclosure comprises instructions which, when executed by a computer, cause the latter to carry out an above-described method according to the disclosure for generating a simplified model for use in an XiL system and/or an above-described method according to the disclosure for carrying out XiL tests.

The present disclosure overall has the advantage that it makes it possible to create XiL systems which can also be implemented for complex models in real time with a reduced computing complexity and with reduced technical requirements.

### BRIEF SUMMARY OF THE DRAWINGS

The disclosure is explained in more detail below on the basis of exemplary embodiments with reference to the accompanying figures. Although the disclosure is described and illustrated more specifically in detail by means of the preferred exemplary embodiments, the invention is not restricted by the disclosed examples and other variations can be derived therefrom by a person skilled in the art without departing from the scope of the claims.

The figures are not necessarily accurate in every detail and true to scale, and may be presented on an enlarged scale or a reduced scale in order to provide a better overview. Therefore, functional details disclosed here are not to be understood as being of a limiting nature but rather merely as an illustrative basis that provides a person skilled in the art in this technological field with guidance for using the present disclosure in a versatile manner

The expression “and/or” used here, when used in a series of two or more elements, means that each of the stated elements may be used individually, or any combination of two or more of the stated elements may be used. For example, if a configuration is described in such a way that it comprises the components A, B and/or C, the configuration may comprise A on its own; B on its own; C on its own; A and B in combination; A and C in combination; B and C in combination; or A, B and C in combination.

FIG. 1 schematically shows, in the form of a flowchart, a method for generating a simplified model for use in an XiL system.

FIG. 2 schematically shows, in the form of a block diagram, a first variant of an arrangement for carrying out XiL tests and its method of operation using a deep neural network.

FIG. 3 schematically shows, in the form of a block diagram, a second variant of an arrangement for carrying out XiL tests and its method of operation using a recurrent neural network.

FIG. 4 schematically shows, in the form of a flowchart, a method for carrying out XiL tests.

### DESCRIPTION

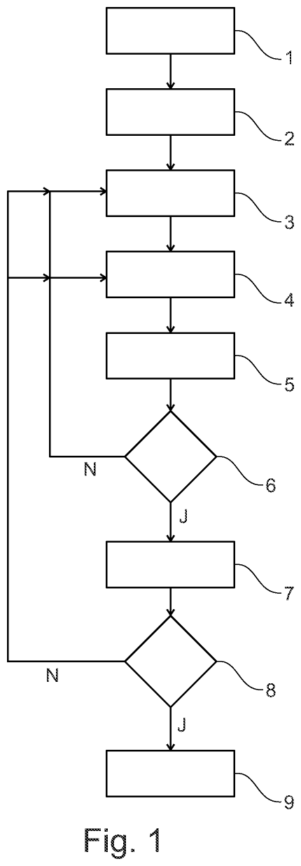

A method for generating a simplified model for use in an XiL system is explained in more detail below on the basis of FIG. 1. In a first step 1, at least one stipulated parameter, which quantitatively characterizes the complexity of a model, is determined for at least one starting model. In this case, the parameter may be stipulated during the method or may have already been stipulated and predefined. It is also possible to determine a plurality of stipulated parameters for the starting model which quantitatively characterize the complexity of the latter.

In a next step 2, input data and output data of the at least one starting model are generated. In step 3, a neural network is trained using a training set of the generated input data and output data of the at least one starting model in order to generate or develop a simplified model, wherein the simplified model has a lower degree of complexity than the at least one starting model, and wherein a stipulated lower threshold value for at least one parameter quantitatively characterizing the reliability of a model is exceeded.

Both the at least one parameter quantitatively characterizing the reliability of a model and the threshold value based thereon may have been predefined or may be individually stipulated during the method.

In a fourth step 4, a simplified model is generated using the trained neural network. In a fifth step, the at least one parameter characterizing the complexity is determined for the simplified model. In a sixth step 6, a check is carried out in order to determine whether the determined complexity of the generated simple model is lower than that of the starting model. If this is the case, the generated simplified model is tested in step 7 using a test set of the generated input data and output data of the at least one starting model, which test set differs from the training set, and the at least one parameter of the generated simplified model, which characterizes the reliability, is determined. If the determined complexity of the generated simplified model is not lower than that of the starting model in step 6, the method jumps back to step 3 or 4.

After step 7, a check is carried out in step 8 in order to determine whether the determined reliability of the simplified model exceeds the stipulated threshold value. If this is the case, the simplified model is output in step 9. If this is not the case, the method jumps back to step 3 or 4.

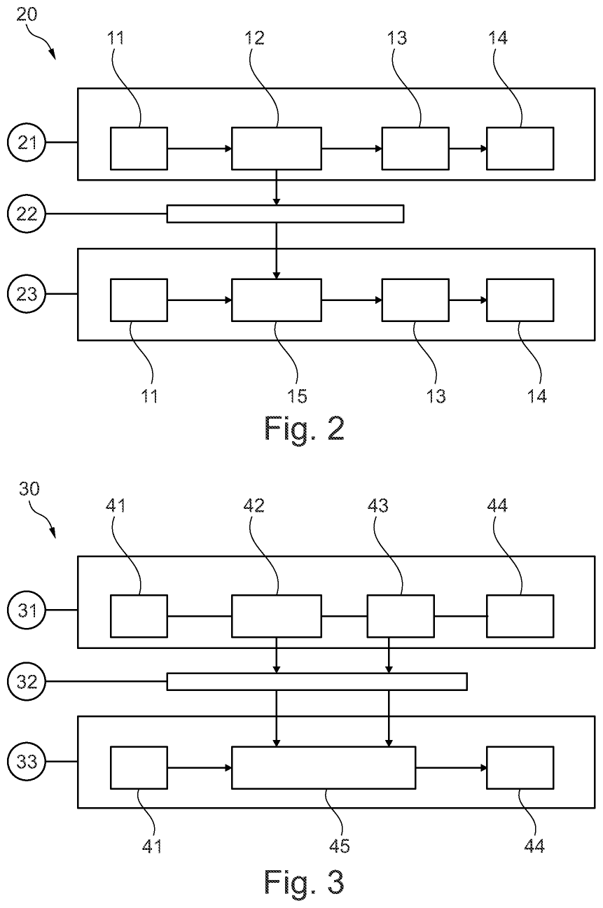

FIG. 2 illustrates, in the form of a block diagram, the present disclosure, specifically a first variant of an arrangement according to the disclosure for carrying out XiL tests 20 and its method of operation if a deep neural network is used. Block 21 is an XiL system or an arrangement for carrying out XiL tests, which comprises a number of XiL models.

An XiL model A is identified using the reference numeral 11. An XiL model B is identified using the reference numeral 12 and an XiL model C is identified using the reference numeral 13. Furthermore, the XiL system 21 comprises a vehicle hardware component 14. The XiL system 21 is configured in such a manner that output data of the XiL model A 11 constitute the input data of the XiL model B 12 and output data of the XiL model B 12 form the input data of the XiL model C 13. The output data of the XiL model C 13 form the input data for the hardware component 14. In the variant shown, the XiL model B 12 is so complex that it cannot be implemented in real time.

The XiL units shown and the underlying models 11, 12 and 13 can be assigned to specific vehicle components or vehicle functions. For example, the XiL system 21 may represent a driver assistance system, also called an ADAS system (Advanced Driver Assistance System). In this case, the XiL model A 11 may represent a sensor model, the XiL model B 12 may represent an ADAS ECU model and the XiL model C 13 may represent a motor control unit or ECU, wherein the vehicle hardware may take place on a chassis dynamometer. These models may also be implemented in a computing unit, for example dSpace Micro Box, having an I/O interface. They may likewise be part of a model-based simulation system or a corresponding toolset.

Block 22 in FIG. 2 represents a device for simplifying a model using a deep neural network (DNN), abbreviated to a model simplifier below. This may be a device, for example a computer program, which is designed to carry out a method described on the basis of FIG. 1. The model simplifier 22 is used to convert the complex XiL model B 12 into an AI-based model, that is to say a model based on artificial intelligence, which can be implemented in real time. For this purpose, the XiL model B 12 is replaced in the system 21 with the AI-based XiL model B 15 newly generated in this manner The XiL system newly generated in this manner is illustrated as block 23 in FIG. 2. It comprises the components of the XiL system 21, wherein the XiL model B 12 has been replaced with the XiL model B 15.

In contrast to the XiL system 21, the new XiL system 23 can be implemented in real time. It requires less computing power for its implementation, in particular, and has lower technical requirements. The new AI-based XiL model B 15 comprises trained weights of the model and is used solely for predictions. It can be implemented, for example, in a computing hardware environment, for example dSpace Microbox, Raspberry PI or on the desktop of a computer. It may also have been or be connected to other XiL models via different communication interfaces, for example CAN, Ethernet (TCP/IP, UDP connectors, etc.). In a similar manner, the model simplifier 22 uses a computing hardware environment. However, this has high performance requirements and requires a high computing power since a neural network must be trained in this context and the training is a computationally complicated process.

A further embodiment variant of an arrangement for carrying out XiL tests 30 is shown in FIG. 3 in the form of a block diagram. In this variant, the starting XiL system 31 comprises four XiL models A, B, C and D which are connected in series, are identified using the reference numerals 41 to 44 and in each of which the output data of the upstream model form the input data of the downstream model. On account of the high degree of complexity of the XiL models B 42 and C 43, the system 31 cannot be implemented in real time. Therefore, a model simplifier, which is illustrated as block 32, is used to transform the XiL models B 42 and C 43 into a common XiL model 45. This is carried out using a recurrent neural network (RNN), e.g., according to a method illustrated in FIG. 1. The AI-based XiL model 45 which is generated in this manner and replaces the XiL models B 42 and C 43 is less complex than the XiL models B 42 and C 43 and requires lower technical complexity when used.

The AI-based XiL model 45 can be generated in a computing unit, for example in Raspberry Pi, dSpace Microbox or a computer. The model generated in this manner includes trained weights of the model and is used solely for predictions. The generated XiL model 45 is designed to be connected to other XiL apparatuses, for example the XiL models A 41 and D 44, for the purpose of transmitting data. For this purpose, the generated AI-based XiL model 45 has communication interfaces which, for example, allow communication using CAN and Ethernet, in particular.

The model simplifier 32 is likewise implemented in a computing environment which, however, requires a higher computing power than the implementation of the XiL system 33. The recurrent neural network 32 is trained in a similar manner to the deep neural network 22 shown in FIG. 2. As a result of the method shown in FIG. 3, a new XiL system 33 is generated, in which the XiL models B 42 and C 43 have been replaced with the XiL model 45 and the system can be implemented in real time as a result.

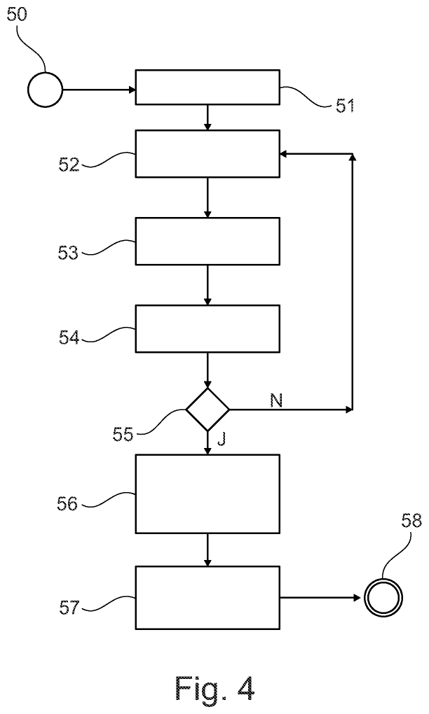

FIG. 4 schematically shows a flowchart which describes the generation of an AI-based simplified model using the example of a deep neural network and illustrates its use during a method for carrying out XiL tests. The method can also be used in a similar manner for a recurrent deep neural network.

After the method has been started 50, an XiL system is initialized in step 51, for example an XiL system identified using the reference numeral 21 in FIG. 2 or an XiL system identified using the reference numeral 31 in FIG. 3. In step 52, input and output data of the model are then generated, which model is too complex for a real-time application, that is to say for the XiL model B 12 in FIG. 2 or the XiL models B 42 and C 43 in FIG. 3, for example. In step 53, the generated data are then used to train a neural network, for example a deep neural network or a recurrent deep neural network, in order to generate a simplified XiL model.

In step 54, a model generated using the neural network is tested with respect to its reliability using the input and output data generated in step 52. In step 55, the reliability is checked with regard to a defined limit value. If the reliability undershoots the stipulated limit value, the method jumps back to step 52. If the reliability exceeds the stipulated limit value, the complex starting model, that is to say the XiL model B 12 in FIG. 2 or the XiL models B 42 and C 43 in FIG. 3 for example, is replaced in step 56 with the generated AI-based XiL model, that is to say the XiL model 15 in FIG. 2 or the XiL model 45 in FIG. 3 for example. The XiL system is then started with the replaced model in step 57 and the method is ended with step 58.

### List of Reference Signs

1 Determine at least one stipulated parameter, which quantitatively characterizes the complexity of a model, for at least one starting model

2 Generate input data and output data of the at least one starting model

3 Train a neural network using a training set of the generated input data and output data of the at least one starting model in order to generate a simplified model which has a lower degree of complexity than the at least one starting model and in which a stipulated lower threshold value for at least one parameter quantitatively characterizing the reliability of a model is exceeded

4 Generate a simplified model using the trained neural network

5 Determine the at least one parameter, which characterizes the complexity, for the simplified model

6 Check whether the determined complexity of the generated simplified model is lower than that of the starting model

7 If the determined complexity of the generated simplified model is lower than that of the starting model, test the generated simplified model using a test set of the generated input data and output data of the at least one starting model, which test set differs from the training set, and determine the at least one parameter of the generated simplified model which characterizes the reliability

8 Check whether the determined reliability of the simplified model exceeds the stipulated threshold value

9 If the determined reliability of the simplified model exceeds the stipulated threshold value, output the simplified model

11 XiL model A

12 XiL model B

13 XiL model C

14 Vehicle hardware component

15 Simplified XiL model

20 Arrangement for carrying out XiL tests

21 XiL system

222 Device for simplifying a model using a deep neural network

23 Newly generated XiL system

30 Arrangement for carrying out XiL tests

31 XiL system

32 Device for simplifying a model using a recurrent neural network

33 Newly generated XiL system

41 XiL model A

42 XiL model B

43 XiL model C

44 XiL model D

45 Simplified XiL model

50 Start

51 Initialize XiL system

52 Generate input and output data of the complex model

53 Train a neural network

54 Test the generated model with respect to its reliability

55 Limit value for reliability exceeded?

56 Replace complex XiL model with AI-based XiL model

57 Start use of the XiL system

58 End

J Yes

N No

1-17. (canceled)

18. A method for carrying out XiL tests, comprising:
determining at least one stipulated parameter that quantitatively characterizes a complexity of at least one starting model;
generating input data and output data of the at least one starting model,
training a neural network using a training set of the generated input data and output data of the at least one starting model to generate a simplified model that has a lower complexity than the at least one starting model, and in which a stipulated lower threshold value for at least one parameter quantitatively characterizing the reliability of a model is exceeded;
generating a simplified model using the trained neural network;
determining the at least one parameter, which characterizes the complexity of the simplified model;
upon determining that the determined complexity of the generated simplified model is lower than that of the starting model, testing the generated simplified model using a test set of the generated input and output data of the at least one starting model, which test set differs from the training set, and determining the at least one parameter of the generated simplified model which characterizes the reliability;
upon determining that the determined reliability of the simplified model exceeds the stipulated threshold value, outputting the simplified model.

19. The method of claim 18, wherein the parameter which quantitatively characterizes the complexity of the starting model comprises at least one of a number of computing operations for each input data item, a required computing time for executing an algorithm representing the model, or a required storage space requirement for executing an algorithm representing the model.

20. The method of claim 18, wherein the parameter which quantitatively characterizes the reliability of the starting model comprises a measure of the deviation of the output data generated by the model from expected output data.

21. The method of claim 18, wherein the neural network is a deep neural network.

22. The method of claim 18, wherein the at least one starting model includes sequence of a number of models.

23. The method of claim 18, wherein the neural network is a recurrent neural network.

24. The method of claim 18, further comprising generating a model for simulating at least one function of a motor vehicle.

25. A system comprising a computing device programmed for carrying out XiL tests, including programming for:
determining at least one stipulated parameter that quantitatively characterizes a complexity of at least one starting model;
generating input data and output data of the at least one starting model,
training a neural network using a training set of the generated input data and output data of the at least one starting model to generate a simplified model that has a lower complexity than the at least one starting model, and in which a stipulated lower threshold value for at least one parameter quantitatively characterizing the reliability of a model is exceeded;
generating a simplified model using the trained neural network;
determining the at least one parameter, which characterizes the complexity of the simplified model;
upon determining that the determined complexity of the generated simplified model is lower than that of the starting model, testing the generated simplified model using a test set of the generated input and output data of the at least one starting model, which test set differs from the training set, and determining the at least one parameter of the generated simplified model which characterizes the reliability;
upon determining that the determined reliability of the simplified model exceeds the stipulated threshold value, outputting the simplified model.

26. The system of claim 25, wherein the parameter which quantitatively characterizes the complexity of the starting model comprises at least one of a number of computing operations for each input data item, a required computing time for executing an algorithm representing the model, or a required storage space requirement for executing an algorithm representing the model.

27. The system of claim 25, wherein the parameter which quantitatively characterizes the reliability of the starting model comprises a measure of the deviation of the output data generated by the model from expected output data.

28. The system of claim 25, wherein the neural network is a deep neural network.

29. The system of claim 25, wherein the at least one starting model includes sequence of a number of models.

30. The system of claim 25, wherein the neural network is a recurrent neural network.

31. The system of claim 25, wherein the computer is further programmed for generating a model for simulating at least one function of a motor vehicle.
